(19) United States
(12) Patent Application Publication
(10) Pub. No.: US 2005/0126482 A1
(43) Pub. Date: Jun. 16, 2005

(54) Forming thin film on semiconductor wafer

(76) Inventors: Myung-Koo Jeong, Suwon-si (KR); Jeong-Ho Yoo, Suwon-si (KR)

Correspondence Address: Robert E. Bushnell, Suite 300, 1522 K Street, N.W., Washington, DC, 20005, US

(21) Appl. No.: 10/839,710

(22) Filed: May 6, 2004

(30) Foreign Application Priority Data
Dec. 15, 2003 (KR) 2003-00091246

(51) Int. Cl. C23C 16/00

(52) U.S. Cl. 118/715; 438/758; 438/787

(57) ABSTRACT

A system and method of forming a thin film on a semiconductor wafer includes: a reaction tube adapted to provide a sealed space to process a wafer; dual wafer loading boats including a first wafer loading boat and a second wafer loading boat, the first wafer loading boat arranged within the sealed space of the reaction tube, the second wafer loading boat arranged adjacent to either an internal side or an external side of the first wafer loading boat; a gap adjusting unit arranged at a lower portion of the dual wafer loading boats; and a gas supplying unit adapted to supply at least one process gas to the reaction chamber.

### CLAIM OF PRIORITY AND CROSS-REFERENCE TO RELATED APPLICATIONS

This application makes reference to, incorporates the same herein, and claims all benefits accruing under 35 U.S.C. § 119 from an application for SEMICONDUCTOR MANUFACTURING, SYSTEM FOR HIGH TEMPERATURE PROCESSES filed in the Korean earlier filed in the Korean Intellectual Property Office on 15 Dec. 2003 and there duly assigned Serial No. 2003-91246. Furthermore, the present application is related to a co-pending U.S. applications, Serial No. (to be determined), entitled SEMICONDUCTOR MANUFACTURING SYSTEM AND WAFER HOLDER FOR SEMICONDUCTOR MANUFACTURING SYSTEM, based upon Korean Patent Application Serial No. 2004-0003072 filed in the Korean Intellectual Property Office on 15 Jan. 2004, and filed in the U.S. Patent & Trademark Office concurrently with the present application.

### BACKGROUND OF THE INVENTION

1. Field of the Invention

The present invention relates to a forming a thin film on a semiconductor wafer when a plurality of wafers are processed, and more particularly, to a batch wafer type semiconductor manufacturing system and method of forming a thin film on a wafer at a relatively high temperature.

2. Description of the Related Art

Semiconductor manufacturing systems for processing a wafer include a batch wafer type semiconductor manufacturing system including a wafer loading boat for loading a plurality of wafers therein so as to improve processing capability and a single wafer type semiconductor manufacturing system for reducing a process time to process the wafer sheet by sheet.

### SUMMARY OF THE INVENTION

The present invention is directed to a semiconductor manufacturing system and method of forming a thin film on a wafer that substantially obviates one or more problems due to the limitations and disadvantages of the related art.

An object of the present invention is to provide a semiconductor manufacturing system and method of forming a thin film on a wafer in which the film is formed only on a front surface of a large-diameter wafer without being formed on a back surface thereof, in a CVD process, for example, to solve processing drawbacks caused by a film being formed on the back surface of the wafer, thereby significantly improving the productivity of the entire semiconductor manufacturing process.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims as well as the appended drawings.

To achieve these objects and other advantages and in accordance with the purpose of the invention, as embodied and broadly described herein, a semiconductor manufacturing system is provided including: a reaction tube adapted to provide a sealed space to process at least one wafer; dual wafer loading boats including a first wafer loading boat and a second wafer loading boat, the first wafer loading boat arranged within the sealed space of the reaction tube and adapted to load at least one wafer therein and having a first wafer support to support a wafer holder to support the at least one wafer to prevent a deposition of a film on a back surface of the at least one wafer, and the second wafer loading boat arranged adjacent to either an internal side or an external side of the first wafer loading boat and adapted to move up and down with respect to the first wafer loading boat and having a second wafer support to independently support an edge portion of the at least one wafer; and a gap adjusting unit arranged on a lower portion of the dual wafer loading boats and adapted to respectively independently support the lower portions of the first wafer loading boat and the second wafer loading boat while moving one of the first and second wafer loading boats up and down to adjust a support state of the at least one wafer.

Preferably, the first wafer loading boat comprises: first support pillars arranged in parallel to form a circular pillar-shaped internal space with one sidewall being open; a first upper connection part and a first lower connection part adapted to respectively support upper and lower sides of the first support pillars; and holder supports arranged on the first support pillars and adapted to partially support an edge portion of the wafer holder in a lengthwise direction.

Preferably, the second wafer loading boat comprises: second support pillars arranged in parallel to form a circular pillar-shaped internal space with one sidewall being open; and a second upper connection part and a second lower connection part adapted to respectively support upper and lower sides of the second support pillars; wherein the second wafer supports are arranged on the second support pillars and adapted to support the edge portion of the wafer in a lengthwise direction.

Preferably, the first support pillar is concave to have a central depressed space in section, and wherein the depressed space houses at least one part of the second support pillar therein.

Preferably, the first support pillar is ‘ [symbol] ’-shaped in section.

Preferably, the first support pillar is cylinder-shaped to have one open side in section.

Preferably, the second support pillar is polygonal rod-shaped to have a polygonal section.

Preferably, the second support pillar is pillar rod-shaped to have a circular section.

Preferably, the first support pillar is concave to have a central depressed space in section, and wherein the depressed space houses at least one part of the second support pillar therein.

Preferably, the first support pillar is ‘ [symbol] ’-shaped in section.

Preferably, the first support pillar is cylinder-shaped to have one open side in section.

Preferably, the second support pillar is polygonal rod-shaped to have a polygonal section.

Preferably, the second support pillar is pillar rod-shaped to have a circular section.

Preferably, the wafer holder comprises: a circular flat holder body; a wafer side-portion guarding part arranged on a flat surface of the holder body and adapted to cut off a side portion of the wafer to prevent a process gas from passing therebetween; and a cut-out part arranged on the flat surface of the holder body corresponding to a second wafer support such that the second wafer support can pass therethrough.

Preferably, the wafer side-portion guarding part comprises a pocket-shaped depression of a chosen depth in the flat surface of the holder body.

Preferably, the wafer side-portion guarding part comprises a ring shape protruding from an upper surface of the holder body along a circumference edge portion of the wafer.

Preferably, the wafer side-portion guarding part is arranged at an edge end portion of the holder body.

Preferably, the wafer side-portion guarding part is arranged at an internal side distance away from an edge portion of the holder body.

Preferably, the wafer side-portion guarding part comprises a taper-shape in contact with the edge portion of the wafer and having a predetermined slanting angle with respect to the flat surface of the holder body.

Preferably, the gap adjusting unit further comprises a rotation driving unit coupled to one of the first wafer and second wafer loading boats and adapted to rotate one of the first wafer and second wafer loading boats such that the wafer rotates on its own axis.

To also achieve these objects and other advantages and in accordance with the purpose of the invention, as embodied and broadly described herein, a semiconductor manufacturing method is provided including: loading a wafer on a wafer holder in dual boats comprised of first and second wafer loading boats, the first wafer loading boat having a holder support arranged in a lengthwise up and down direction and at a distance to support a wafer holder, and the second wafer loading boat having a wafer support arranged in a lengthwise direction for supporting the wafer resting on the wafer holder; inserting the dual boats into a reaction tube, sealing a process space, and supplying a process gas to the process space to effect a process of forming a thin film on the wafer; after a predetermined time period, intermittently separating the wafer from the wafer holder at least one time for another predetermined time and by a predetermined height; and withdrawing the dual boats to unload the wafer after the process has been completed.

Preferably, supplying the process gas comprises supplying a gas to form any one of a silicon nitride film, a silicon oxide film, a polysilicon film, and an epitaxial silicon film.

Preferably, the predetermined height for separating the wafer from a holder body is not larger than a gap between wafer supports.

Preferably, an inert gas is supplied while the wafer is being separated from the holder body.

Preferably, the another predetermined time is determined by a film thickness to be formed on the wafer.

Preferably, separating the wafer from the wafer holder further comprises rotating the wafer.

To also achieve these objects and other advantages and in accordance with the purpose of the invention, as embodied and broadly described herein, a semiconductor manufacturing method is provided including: separating one wafer loading boat from another loading boat for supporting a wafer holder to load a wafer on the one wafer loading boat; during a process of forming a thin film on the wafer, raising or lowering the one wafer loading boat at least one time to seat the wafer on the wafer holder; and separating the one wafer loading boat from the wafer holder to unload only the wafer after the process has been completed.

As described above, in the inventive semiconductor manufacturing system, the wafer side-portion guarding part is arranged at the wafer holder on which the wafer rests such that the process gas does not penetrate into the back surface of the wafer, thereby preventing a film from being formed on the back surface of the wafer. Accordingly, processing failures occurring in subsequent processes due to an unwanted film deposited being formed on the back surface of the wafer can be greatly reduced.

Additionally, since the inventive film forming method separates the wafer from the wafer holder at a predetermined time interval while the film is being deposited, the wafer adherence phenomenon can be prevented during the forming of the film. Accordingly, the release of spurious particles while the wafer is being unloaded due to adherence of the edge portion of the wafer to the wafer holder when a thick film is formed can be obviated.

It is to be understood that both the foregoing general description and the following detailed description of the present invention are exemplary and explanatory and are intended to provide further explanation of the invention as claimed.

### BRIEF DESCRIPTION OF THE DRAWINGS

A more complete appreciation of the present invention, and many of the attendant advantages thereof, will become readily apparent as the same becomes better understood by reference to the following detailed description when considered in conjunction with the accompanying drawings in which like reference symbols indicate the same or similar components, wherein:

FIG. 1A is a schematic section view of a batch type semiconductor manufacturing system;

FIG. 1B is an upper plan view of FIG. 1A and an expanded section view of an ‘A’ portion of FIG. 1A;

FIG. 2 is a schematic section view of a semiconductor manufacturing system according to an exemplary embodiment of the present invention;

FIGS. 3A and 3B are a side section view and a plan view as expanded views of a ‘B’ portion of FIG. 2, of a wafer holder arranged in a semiconductor manufacturing system according to an exemplary embodiment of the present invention;

FIGS. 4A and 4B are a plan view and a section view of a wafer holder according to a first embodiment of the present invention;

FIGS. 5A and 5B are a plan view and a section view of a wafer holder according to a second embodiment of the present invention;

FIGS. 6A and 6B are a plan view and a section view of a wafer holder according to a third embodiment of the present invention;

FIGS. 7A and 7B are a plan view and a section view of a wafer holder according to a fourth embodiment of the present invention; and

FIG. 8 is a flowchart of a method of forming a thin film on a wafer according to an exemplary embodiment of the present invention.

### DETAILED DESCRIPTION OF THE INVENTION

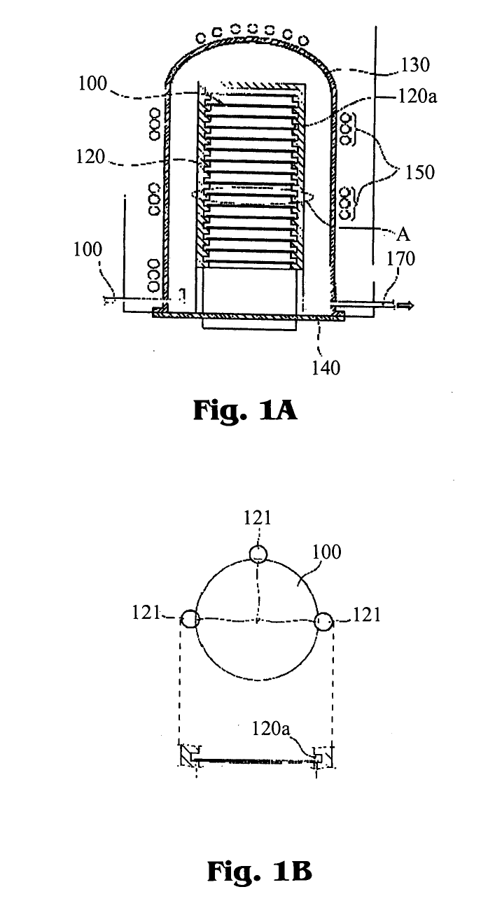

FIG. 1A is a schematic section view of a batch type semiconductor manufacturing system, and FIG. 1B is an upper plan view of FIG. 1A and an expanded section view of an ‘A’ portion of FIG. 1A.

Referring to FIGS. 1A and 1B, the batch wafer type semiconductor manufacturing system includes: a tubular reaction tube 110 having a lower opening portion for forming an internal space for housing therein; a wafer loading boat 120 housed within the reaction tube 110 and having slots 120a for loading a plurality of wafers 100 layered in an up/down direction; a heater 150 surrounding the reaction tube 10 to heat the internal space of the reaction tube 110; and a boat cap 140 for supporting the wafer loading boat 120 at its lower portion and operating to open and close the opening portion of the reaction tube 110. The wafer loading boat 120 is comprised of a plurality of support pillars (reference numeral 121 of FIG. 1B) that are pillar-shaped; the slots 120a are arranged away from one another along the support pillar 121. A gas injecting unit 160 for injecting a process gas and a gas discharging unit 170 for discharging the process gas are arranged on the tubular reaction tube 110.

In the batch wafer type semiconductor manufacturing system shown in FIG. 1B, when the process is performed, a thin film is formed on both surfaces of the wafer 100, the loading boat and the slots for supporting the lower portion of the wafer since the slots support each wafer 100 at its edge portion (P), for example, during a CVD (Chemical Vapor Deposition) process for forming the thin film.

Accordingly, after the CVD process has been completed, a great number of impurity particles are shed by the back surface of the wafer. Furthermore, since a film uniformity of the back surface of the wafer is also significantly reduced in comparison with a film uniformity of a front surface of the wafer, many process drawbacks occur during subsequent processes, specifically, during photolithography. Since the wafer is of a large diameter (for example, 200 mm or 300 mm) and a pattern size is fine (for example, below 0.15 micron), the film deposited on the back surface of the wafer is a significant cause of serious processing failures during the subsequent photolithography. Furthermore, the film formed on the front surface of the wafer is almost entirely etched out except for a portion of the film required in subsequent photolithography and etching processes, whereas the film formed on the back surface of the wafer is processed as is even in subsequent processes if a special process for removing the film from the back surface is not performed. In a subsequent high temperature heat-treatment process, film stress occurs due to the film on the back surface of the wafer, and as a result, the entire wafer is distorted, thereby causing processing failures. Furthermore, the film formed on the back surface of the wafer causes emissivity variations even during a rapid thermal process (RTP) for measuring a temperature using the emissivity of the back surface of the wafer, thereby making it impossible to exactly measure the temperature and thereby causing processing failures.

Reference will now be made in detail to the exemplary embodiments of the present invention, examples of which are illustrated in the accompanying drawings.

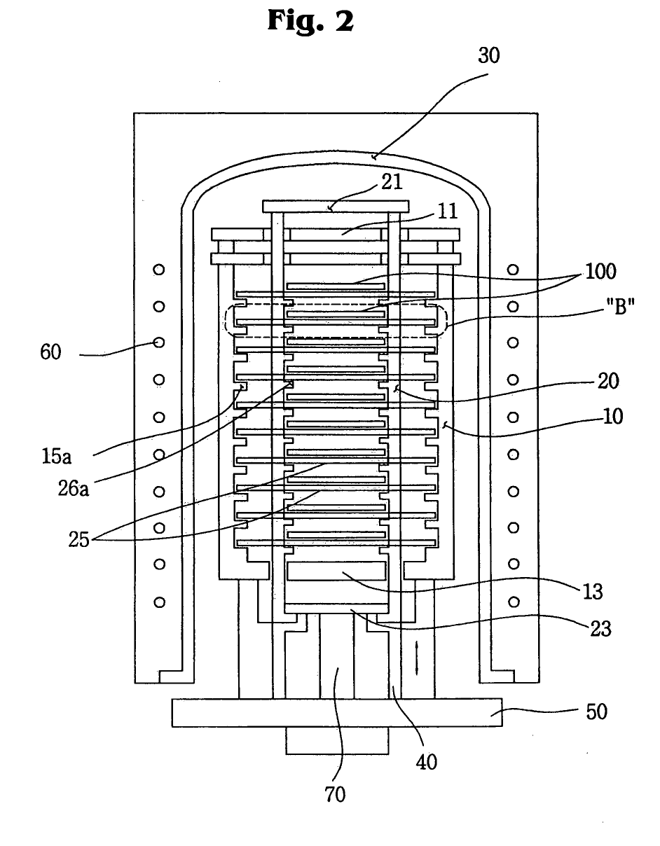

FIG. 2 is a schematic section view of a semiconductor manufacturing system according to an embodiment of the present invention.

Referring to FIG. 2, the semiconductor manufacturing system according to an embodiment of the present invention includes a reaction tube 30 for providing a sealed space for performing a process therein; dual wafer loading boats 10 and 20 comprised of a first wafer loading boat 10 and a second wafer loading boat 20, the first wafer loading boat 10 supporting a wafer holder 25 for loading a plurality of wafers 100 thereon while inserting and withdrawing into and from the reaction tube 30, the second wafer loading boat 20 having a wafer support 26a for independently supporting the wafer 100 loaded on the wafer holder 25; and a gap adjusting unit 70 (or boat driving unit) arranged on the lower sides of the dual wafer loading boats 10 and 20 to independently support the lower portions of the first and second loading boats 10 and 20. Additionally, it includes a heating unit 60 encompassing an outer portion of the reaction tube 30 to heat an internal space of the reaction tube 30 to a predetermined temperature; and a door plate 50 moving up and down while supporting the lower portions of the dual wafer loading boats 10 and 20 to insert into or withdraw from the reaction tube 30.

The gap adjusting unit 70 concurrently and separately supports the first and second wafer loading boats 10 and 20 and minutely moves up and down. Accordingly, the gap adjusting unit 70 can be used to load and unload the wafer 100 on the wafer holder 25. A contact state of the wafer 100 can be arbitrarily adjusted on the wafer holder 25. Additionally, according to need, it can include a rotation driving unit (not shown) for rotating the dual wafer loading boats 10 and 20 to rotate the wafer 100 on its own axis.

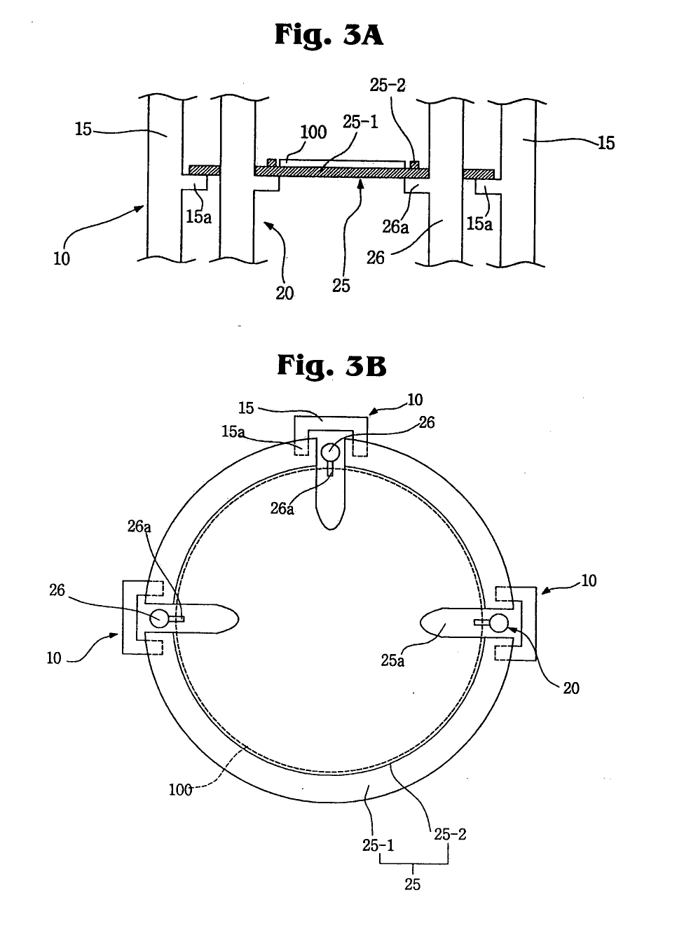

FIGS. 3A and 3B are a side section view and a plan view as expanded views of a ‘B’ portion of FIG. 2, of a wafer holder of a semiconductor manufacturing system according to an embodiment of the present invention.

Referring to FIGS. 3A and 3B, the dual wafer loading boats 10 and 20 include the first wafer loading boat 10 and the second wafer loading boat 20 respectively arranged in parallel at its internal and external sides. The first wafer loading boat 10 supports the wafer holder 25, and the second wafer loading boat 20 partially supports an edge portion of the wafer 100.

The first wafer loading boat 10 is comprised of at least three first support pillars 15. Their internal portions are circular pillar-shaped and their sidewalls are arranged in parallel to form opened spaces. A first upper connection part (reference numeral 11 of FIG. 2) and a first lower connection part (reference numeral 13 of FIG. 2) of the upper and lower end portions of the first support pillar 15 are respectively arranged to support and fix the first support pillars 15 in the same plane. Additionally, a holder support 15a is arranged at an internal side of the first support pillar 15 to support an edge portion of the wafer holder 25. A plurality of holder supports 15a are arranged in a lengthwise direction and at a distance along the first support pillar 15. The holder supports 15a can be of a slot type shape or can be of a protruded type shape as shown.

The second wafer loading boat 20 is comprised of at least three second support pillars 26 similar to the first wafer loading boat 10, and their internal portions are pillar-shaped and their sidewalls are arranged in parallel to form opened spaces. A second upper connection part 21 and a second lower connection part 23 are respectively arranged on upper and lower end portions of the second support pillar 26 to support and fix the second support pillars 26 in the same plane. Additionally, a wafer support 26a is arranged on an internal side of the second support pillar 26 to partially support an edge portion of the wafer 100 arranged on the wafer holder 25. The wafer support 26a is arranged in a lengthwise direction and at a distance along the second support pillar 26 corresponding to a position of the holder support 15a. The wafer support 26a can be of a slot type shape or can be of a protruded type shape.

It is desirable for the first and second support pillars 15 and 26 to be arranged at different positions, not on the same geometric plane and circumference. This is because a supporting point of the holder support 15a disappears from the wafer holder 25 when a holder support 15a portion and a wafer support 26a portion of the wafer holder 25 described later are overlapped.

Referring to FIG. 3B, if the first support pillar 15 is concave in section and arranged within the dual wafer loading boats, then the second support pillar 26 having a polygonal rod-shape is housed in a concave space of the support pillar 15. Accordingly, the wafer support 26a or the holder support 15a can be arranged without overlapping of the supporting point even though the first and second support pillars 15 and 26 are arranged at the same position. The second support pillar 26 is a circular pillar or a polygonal pillar having a triangular, square or hexagonal crossection, and the wafer support 26a protruding into an internal area of the dual wafer loading boats 10 and 20 is arranged along a lengthwise direction of the second support pillar 26. Furthermore, the first support pillar 15 can be concave in section such as a ‘ [symbol] ’-shape, or can be a cylinder-shape with one side being open.

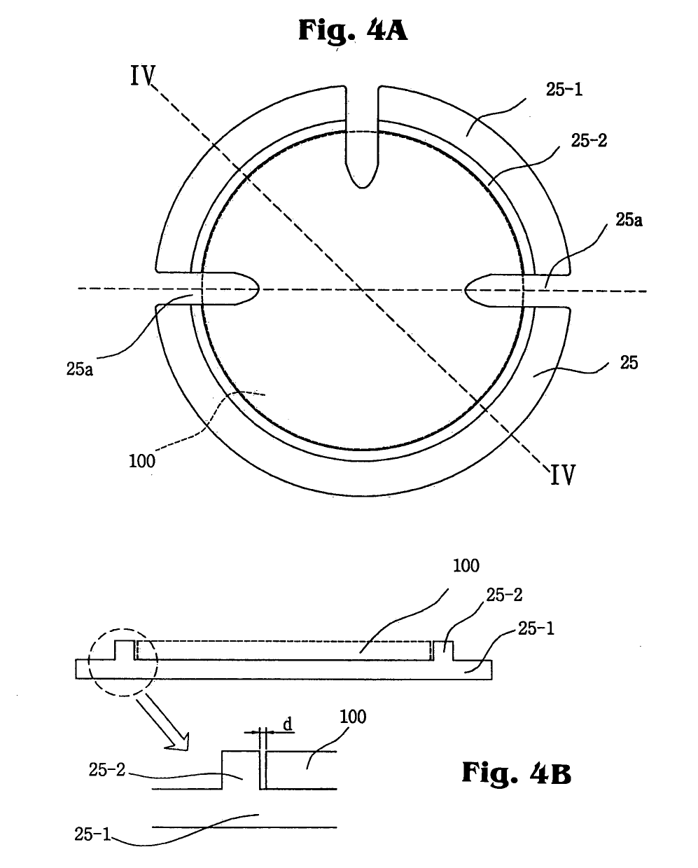

FIGS. 4A and 4B are a plan view and a section view of a wafer holder according to a first embodiment of the present invention.

Referring to FIGS. 4A and 4B, the wafer holder 25 includes a circular plate-shaped holder body 25-1; a cut-out part 25a formed by cutting out an overlap portion of the wafer support 26a portion to be a certain shape; and a wafer side-portion guarding part 25-2 arranged on a flat surface of the holder body 25-1 to be closely adjacent to a side edge portion of the wafer 100 for preventing the process gas from flowing therebetween. The wafer side-portion guarding part 25-2 is ring-shaped and protrudes from the flat surface of the holder body 25 by a height corresponding to a thickness of the wafer 100 along an edge end portion of the wafer 100. The wafer 100 is housed within the ring-shaped wafer side-portion guarding part 25-2. Accordingly, the wafer side-portion guarding part 25-2 prevents the side portion of the wafer 100 from being directly exposed to the process gas, and prevents the process gas from entering between the back surface of the wafer 100 and the wafer holder 25 in contact therewith. Therefore, the front surface of the wafer 100 is entirely exposed to the process gas such that the film is formed on the front surface of the wafer 100. The back surface of the wafer 100 does not have the film deposited thereon due to the wafer side-portion guarding part 25-2. As shown in the expanded view, a gap (d) between the side surface of the wafer 100 and the wafer side-portion guarding part 25-2 is chosen in accordance with a flow rate of the process gas. That is, a size of the gap (d) is adjusted to prevent the process gas from entering into the gap (d) to flow to the back surface of the wafer 100. In order to load the wafer 100, the gap (d) should be secured to some degrees. At less than a predetermined gap, a fluid flowing characteristic is used in which even though the process gas collides with the lower portion of the wafer 100, it does not hydro-mechanically penetrate into the lower portion of the wafer 100.

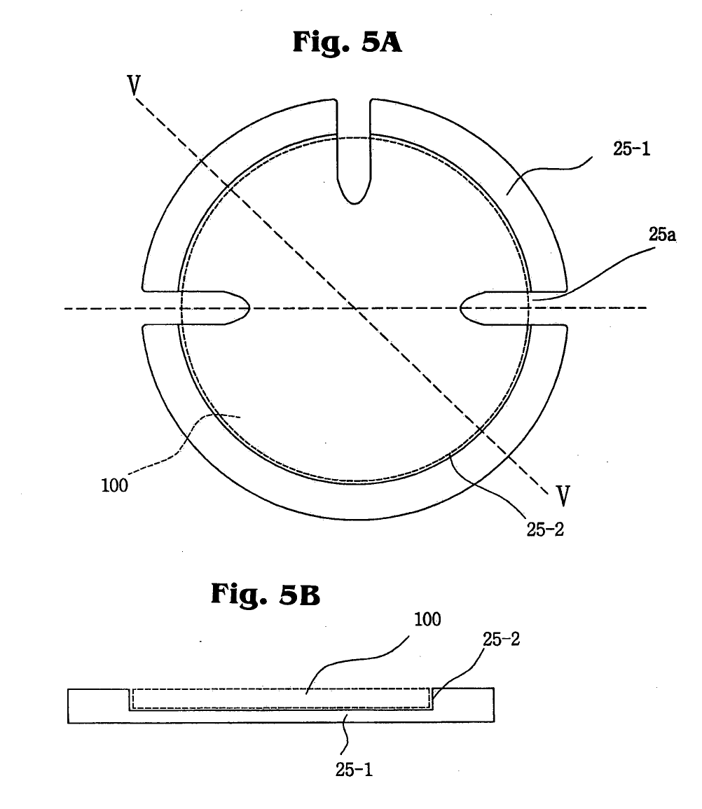

FIGS. 5A and 5B are a plan view and a section view illustrating the wafer holder according to a second embodiment of the present invention.

Referring to FIGS. 5A and 5B, a wafer side-portion guarding part 25-2 for cutting off a side portion of a wafer 100 is pocket-shaped differently from that of FIGS. 4A and 4B. That is, a depressed portion formed by depressing a flat surface of a holder body 25-1 adaptively to a shape of the wafer 100 such that the wafer 100 rests on the depressed portion. Accordingly, it is desirable that the height of the flat surface of the holder body 25-1 is the same or greater than the height of the wafer 100.

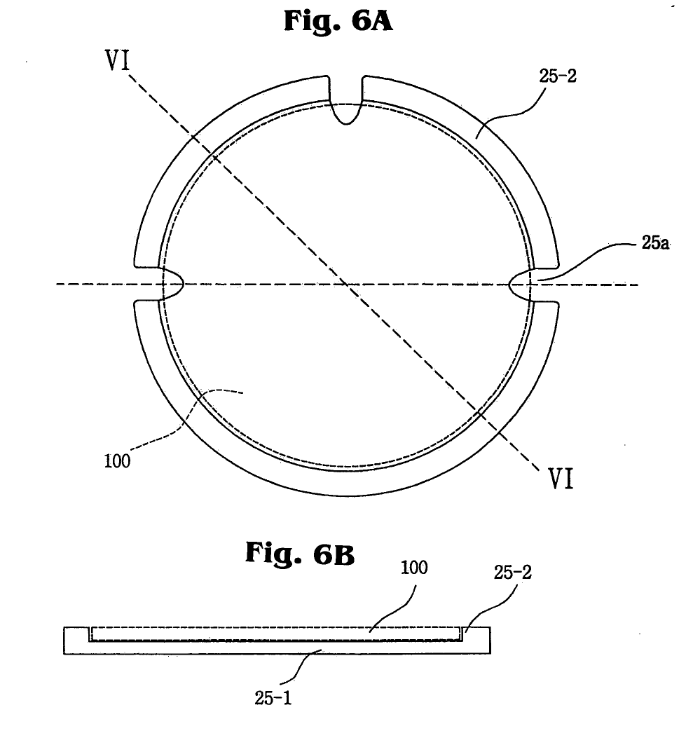

In the embodiments of the FIGS. 5A and 5B and the embodiments of FIGS. 6A and 6B, it is preferable that a wafer side-portion guarding part 25-2 upon which the wafer 100 is located has a size difference greater than the size of the holder body 25-1. That is, it is desirable that a diameter of the ring-shaped or pocket-shaped wafer side-portion guarding part 25-2 is formed corresponding to a uniform jet gas region actually observed when the process gas is jetted to the wafer holder 25. Accordingly, the wafer side-portion guarding part 25-2 upon which the wafer 100 is located can have very small-sized diameter as compared to the diameter of the wafer holder 25, and accordingly, the film uniformity of the wafer 100 can be greatly improved.

FIGS. 6A and 6B are a plan view and a section view illustrating the wafer holder according to a third embodiment of the present invention.

Referring to FIGS. 6A and 6B, a wafer holder 25 includes a circular plate-shaped holder body 25-1; and a wafer side-portion guarding part 25-2 protruded upwardly with respect to a flat surface along an edge corner region of the holder body 25-1. Additionally, a cut-out part 25a is formed on the flat surface of the holder body 25-1 by cutting out a portion of the flat surface of the holder body 25-1 to allow the second wafer loading boat 20 and the wafer support 26a to pass up and down.

The wafer holder 25 has an advantage in that the wafer holder 25 can be manufactured to be similar in size to that of the wafer 100 to make the dual wafer loading boats 10 and 20 compact in size.

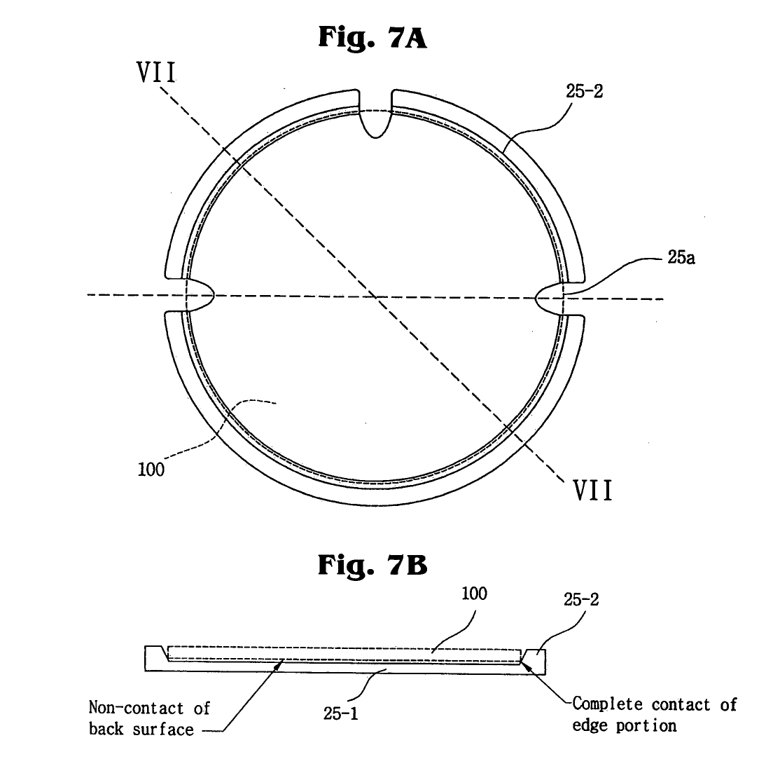

FIGS. 7A and 7B are a plan view and a section view illustrating the wafer holder according to a fourth embodiment of the present invention.

Referring to FIGS. 7A and 7B, other structural elements are similar as described above, but a wafer side-portion guarding part 25-2 is tapered slanting at a contact portion with a wafer 100. Accordingly, if the wafer 100 rests on the holder body 25-1, a corner of the wafer 100 is in contact with a sidewall of the wafer side-portion guarding part 25-2, thereby effectively preventing the process gas from flowing to the back surface of the wafer 100.

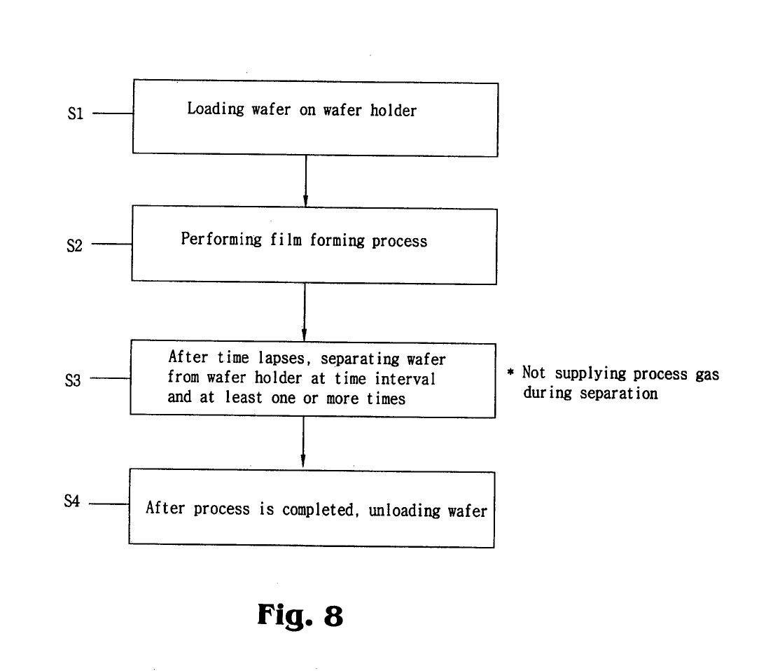

FIG. 8 is a flowchart of a method of forming a thin film on the wafer according to an exemplary embodiment of the present invention.

Referring to FIG. 8, the wafer 100 is loaded on the wafer holder 25 of FIG. 2 (S1). After the process space is sealed, the process gas is introduced within the reaction tube 30 to start the process (S2). The introduced gas can be a gas for the CVD process, and can be a gas for forming a silicon oxide film, a silicon nitride film, a polysilicon film and an epitaxial silicon film, for example.

A predetermined time after the process has started, the wafer 100 is separated from the wafer holder 25 within a predetermined time interval, at least one time and by a predetermined height (S3). At this time, the time interval and the times are determined depending on a thickness of the film formed by the film forming process. That is, if the film is thick, then the time for separating the wafer 100 from the wafer holder 25 is increased. If the film is thin, then even one time interval is sufficient. After the process is completed, the wafer 100 is unloaded from the wafer holder 25 of the dual wafer loading boats 10 and 20 (S4).

In the wafer separating step, first of all, if the gap adjusting unit 70 moves one of the first and second wafer loading boats 10 and 20 up and down of below one pitch of the wafer support 26a, the wafer support 26a of the second wafer loading boat 20 is elevated up such that the wafer 100 is raised by a predetermined height to be separated from the wafer holder 25. After a predetermined time has passed, the gap adjusting unit 70 moves one of the first and second wafer loading boats 10 and 20 up and down by a minute distance such that an initial wafer 100 is loaded on the wafer holder 25. Accordingly, the wafer support 26a of the second wafer loading boat 20 is lowered such that the wafer 100 is again seated on the wafer holder 25. It is desirable for an inert gas to be supplied instead of the process gas while the wafer 100 is being separated from the wafer holder 25. If the process gas is supplied to an exposed back surface of the wafer 100, then a film is formed on the back surface of the wafer 100.

While the process gas is supplied to deposit the film, the film tends to be deposited even at the contact portion of the wafer 100 with the wafer holder 25, thereby causing adherence to each other because the film is not only deposited on the wafer 100, but is also deposited, even though in small amounts, on the parts arranged within the reaction tube 30, specifically on the wafer holder 25 supporting the wafer 100. In order to prevent this phenomenon, the wafer 100 is separated from the wafer holder 25. Accordingly, a particle drawback or a life drawback of the parts caused by adhering the wafer 100 to the wafer holder 25 can be obviated.

Additionally, in the start step (S2), the dual wafer loading boats 10 and 20 are rotated using the rotation driving unit additionally affixed to the gap adjusting unit 70 such that the wafer can be rotated. Accordingly, the wafer 100 can be rotated during the process, thereby greatly improving the uniformity of the film formed on the wafer 100. At least one of the first and second wafer loading boats 10 and 20 can be rotated using the gap adjusting unit 70 so as to rotate the wafer 100.

It is preferable that the first and second wafer loading boats 10 and 20 and the wafer holder 25 are formed of a quartz or a silicon carbide for high-temperature endurance. Specifically, it is preferable that the wafer holder 25 is formed of silicon carbide to be used for processing at a high temperature of more than 1200° C.

A gas supplying device (not shown) includes a plurality of process gas reservoirs (not shown) to supply the process gas introduced within the reaction tube 30, through the gas supplying unit. If a CVD process is being performed, other process gases can be injected. For example, the gases for the CVD process are supplied to form a silicon oxide film (SiO₂) or a silicon nitride film (SiN) and a polysilcon film, etc. Specifically, in an epitaxial growth deposition process, being one of the high temperature chemical vapor deposition processes, a silicon source gas and a process gas carrier gas and a purge gas can be concurrently supplied. DSC (SiH₂C1₂), TCS (SiHCl₃) and SiCl₄, SiₓH_{y} based gases and the like can be used as the silicon source gas, and H₂ can be used as the carrier gas. N₂ or Ar, He and the like can be used as the inert gas as well as the purge gas.

As described above, since the semiconductor manufacturing system in accordance with the embodiments of the present invention includes the wafer side-portion guarding part for preventing the thin film from being deposited on the back surface of the wafer, the film is not deposited on the back surface of the wafer (that is, back-surface deposition can be prevented). Accordingly, after the film deposition process has been completed, an irregularly formed film is not formed on the back surface of the wafer 100, thereby obviating processing failures due to misalignment in the subsequent photolithography.

Additionally, while the inventive forming process of the thin film is being performed, the gap adjusting unit 70 minutely adjusts the first wafer loading boat 10 or the second wafer loading boat 20 up and down to arbitrarily separate the wafer 100 and the wafer holder 25 therebetween, thereby preventing the adhering of the wafer to the wafer holder while the thick film is being formed during the CVD film forming process.

As described above, in the inventive semiconductor manufacturing system, the wafer side-portion guarding part is arranged on the wafer holder on which the wafer rests such that the process gas does not penetrate into the back surface of the wafer, or the wafer is in contact with the wafer side-portion guarding part tapered at a predetermined angle to prevent the film from being formed on the back surface of the wafer. Accordingly, processing failures occurring in the subsequent processes due to an unwanted film being deposited on the back surface of the wafer can be prevented.

Additionally, since the inventive film forming method can separate the wafer from the wafer holder at a predetermined time interval while the film is being deposited, the wafer adherence phenomenon can be prevented at the time of forming the film, to thereby reduce a particle source of the back surface and greatly improve a stability of the process.

It will be apparent to those skilled in the art that various modifications and variations can be made in the present invention. Thus, it is intended that the present invention covers the modifications and variations of this invention provided they come within the scope of the appended claims and their equivalents.

1. A system comprising:
a reaction tube adapted to provide a sealed space to process at least one wafer;
dual wafer loading boats including a first wafer loading boat and a second wafer loading boat, the first wafer loading boat arranged within the sealed space of the reaction tube and adapted to load at least one wafer therein and having a first wafer support to support a wafer holder to support the at least one wafer to prevent a deposition of a film on a back surface of the at least one wafer, and the second wafer loading boat arranged adjacent to either an internal side or an external side of the first wafer loading boat and adapted to move up and down with respect to the first wafer loading boat and having a second wafer support to independently support an edge portion of the at least one wafer; and
a gap adjusting unit arranged on a lower portion of the dual wafer loading boats and adapted to respectively independently support the lower portions of the first wafer loading boat and the second wafer loading boat while moving one of the first and second wafer loading boats up and down to adjust a support state of the at least one wafer.

2. The system of claim 1, wherein the first wafer loading boat comprises:
first support pillars arranged in parallel to form a circular pillar-shaped internal space with one sidewall being open;
a first upper connection part and a first lower connection part adapted to respectively support upper and lower sides of the first support pillars; and
holder supports arranged on the first support pillars and adapted to partially support an edge portion of the wafer holder in a lengthwise direction.

3. The system of claim 1, wherein the second wafer loading boat comprises:
second support pillars arranged in parallel to form a circular pillar-shaped internal space with one sidewall being open; and
a second upper connection part and a second lower connection part adapted to respectively support upper and lower sides of the second support pillars;
wherein the second wafer supports are arranged on the second support pillars and adapted to support the edge portion of the wafer in a lengthwise direction.

4. The system of claim 2, wherein the first support pillar is concave to have a central depressed space in section, and wherein the depressed space houses at least one part of the second support pillar therein.

5. The system of claim 4, wherein the first support pillar is ‘ [symbol] ’-shaped in section.

6. The system of claim 4, wherein the first support pillar is cylinder-shaped to have one open side in section.

7. The system of claim 4, wherein the second support pillar is polygonal rod-shaped to have a polygonal section.

8. The system of claim 4, wherein the second support pillar is pillar rod-shaped to have a circular section.

9. The system of claim 3, wherein the first support pillar is concave to have a central depressed space in section, and wherein the depressed space houses at least one part of the second support pillar therein.

10. The system of claim 9, wherein the first support pillar is ‘ [symbol] ’-shaped in section.

11. The system of claim 9, wherein the first support pillar is cylinder-shaped to have one open side in section.

12. The system of claim 9, wherein the second support pillar is polygonal rod-shaped to have a polygonal section.

13. The system of claim 9, wherein the second support pillar is pillar rod-shaped to have a circular section.

14. The system of claim 1, wherein the wafer holder comprises:
a circular flat holder body;
a wafer side-portion guarding part arranged on a flat surface of the holder body and adapted to cut off a side portion of the wafer to prevent a process gas from passing therebetween; and
a cut-out part arranged on the flat surface of the holder body corresponding to a second wafer support such that the second wafer support can pass therethrough.

15. The system of claim 14, wherein the wafer side-portion guarding part comprises a pocket-shaped depression of a chosen depth in the flat surface of the holder body.

16. The system of claim 14, wherein the wafer side-portion guarding part comprises a ring shape protruding from an upper surface of the holder body along a circumference edge portion of the wafer.

17. The system of claim 14, wherein the wafer side-portion guarding part is arranged at an edge end portion of the holder body.

18. The system of claim 14, wherein the wafer side-portion guarding part is arranged at an internal side distance away from an edge portion of the holder body.

19. The system of claim 14, wherein the wafer side-portion guarding part comprises a taper-shape in contact with the edge portion of the wafer and having a predetermined slanting angle with respect to the flat surface of the holder body.

20. The system of claim 1, wherein the gap adjusting unit further comprises a rotation driving unit coupled to one of the first wafer and second wafer loading boats and adapted to rotate one of the first wafer and second wafer loading boats such that the wafer rotates on its own axis.

21. A method comprising:
loading a wafer on a wafer holder in dual boats comprised of first and second wafer loading boats, the first wafer loading boat having a holder support arranged in a lengthwise up and down direction and at a distance to support a wafer holder, and the second wafer loading boat having a wafer support arranged in a lengthwise direction for supporting the wafer resting on the wafer holder;
inserting the dual boats into a reaction tube, sealing a process space, and supplying a process gas to the process space to effect a process of forming a thin film on the wafer;
after a predetermined time period, intermittently separating the wafer from the wafer holder at least one time for another predetermined time and by a predetermined height; and
withdrawing the dual boats to unload the wafer after the process has been completed.

22. The method of claim 21, wherein supplying the process gas comprises supplying a gas to form any one of a silicon nitride film, a silicon oxide film, a polysilicon film, and an epitaxial silicon film.

23. The method of claim 21, wherein the predetermined height for separating the wafer from a holder body is not larger than a gap between wafer supports.

24. The method of claim 21, wherein an inert gas is supplied while the wafer is being separated from the holder body.

25. The method of claim 21, wherein the another predetermined time is determined by a film thickness to be formed on the wafer.

26. The method of claim 21, wherein separating the wafer from the wafer holder further comprises rotating the wafer.

27. A method comprising:
separating one wafer loading boat from another loading boat for supporting a wafer holder to load a wafer on the one wafer loading boat;
during a process of forming a thin film on the wafer, raising or lowering the one wafer loading boat at least one time to seat the wafer on the wafer holder; and
separating the one wafer loading boat from the wafer holder to unload only the wafer after the process has been completed.
